(19) United States
(12) Patent Application Publication
(10) Pub. No.: US 2023/0223489 A1
(43) Pub. Date: Jul. 13, 2023

(54) PHOTOVOLTAIC CELL ARRAY AND PHOTOVOLTAIC MODULE

(71) Applicants: ZHEJIANG JINKO SOLAR CO., LTD., Haining (CN); JINKO SOLAR CO., LTD., Jiangxi (CN)

(72) Inventors: Zhiqiu GUO, Haining (CN); Juan WANG, Haining (CN); Changzhen SUN, Haining (CN); Hao JIN, Haining (CN)

(73) Assignees: ZHEJIANG JINKO SOLAR CO., LTD., Haining (CN); JINKO SOLAR CO., LTD., Jiangxi (CN)

(21) Appl. No.: 18/110,132

(22) Filed: Feb. 15, 2023

Related U.S. Application Data
(63) Continuation of application No. 16/766,295, filed on May 22, 2020, now abandoned.

(30) Foreign Application Priority Data
May 28, 2019 (CN) 201910454083.4
May 28, 2019 (CN) 201920785516.X

(51) Int. Cl. H01L 31/05; H01L 31/043

(52) U.S. Cl. CPC H01L 31/0512; H01L 31/043

(57) ABSTRACT

A photovoltaic cell array and a photovoltaic module are provided. The photovoltaic cell array includes multiple solar cells and a flexible metal conductive strip. Each solar cell includes an upper surface, upper segment electrodes, a lower surface, and lower segment electrodes. A first solar cell including a first overlap region is adjacent to a second solar cell including a second overlap region. The second overlap region, a third overlap region of the flexible metal conductive strip, and the first overlap region are sequentially stacked. The flexible metal conductive strip is welded to only one lower segment electrode and only one upper segment electrode. The lower segment electrodes of the first solar cell are outside the first overlap region, and the upper segment electrodes are outside the second overlap region.

### CROSS-REFERENCE TO RELATED APPLICATIONS

This application is a continuation application of U.S. application Ser. No. 16/766,295, filed May 22, 2020, which is a National Phase of International Application No. PCT/CN2019/102127, filed on Aug. 23, 2019, which claims priority to and the benefit of Chinese Patent Application No. 201910454083.4 filed on May 28, 2019 and Chinese Patent Application No. 201920785516.X filed on May 28, 2019. The disclosures of the above applications are incorporated herein by reference.

### FIELD

The present disclosure relates to the technical field of solar cells, and in particular to a photovoltaic cell array and a photovoltaic module.

### BACKGROUND

The statements in this section merely provide background information related to the present disclosure and may not constitute prior art.

With the rapid development of the society, there is an increasing demand for energy. However, there is limited amount of fossil energy, which cannot satisfy the long-period demand of social development. Moreover, consumption of the fossil energy may result in serious environmental pollution. Therefore, in order to promote harmonious development of the society, it is required to develop a new energy to replace the fossil energy. The solar energy, as a renewable energy, has unlimited reserves and is free for use, and no pollutant is caused in the process of using the solar energy. Therefore, photovoltaic industry develops rapidly in recent years.

In order to satisfy the demands for industry development and customers, photovoltaic enterprises have to reduce a power loss inside a photovoltaic module and increase output power of the photovoltaic module. In order to increase the output power of the photovoltaic module, the photovoltaic enterprises introduce multiple photovoltaic module fabricating technologies, such as an imbricate technology. In the imbricate technology, a square (quasi square) solar cell is divided into multiple rectangular (quasi rectangular) sub-solar cells, and a front electrode in one sub-cell and a back electrode in an adjacent sub-solar cell are overlapped with each other via conducting resin to form a series circuit. A current between adjacent sub-solar cells transmits in a direction perpendicular to a surface of the sub-solar cell, such that a current inside the module is small and a light receiving area of the module is large, thereby increasing the power and efficiency of the module.

Compared with a conventional module, although output power of an imbricate photovoltaic module is improved, processes such as applying conducting resin, curing and terminal welding and related devices are additionally required, which results in a complex process and a high production cost. In addition, the conducting resin has a large resistance, resulting in a high loss inside the imbricate photovoltaic module.

### SUMMARY

This section provides a general summary of the disclosure and is not a comprehensive disclosure of its full scope or all of its features.

An object of the present disclosure is to provide a photovoltaic cell array and a photovoltaic module, which have increased output power and reduced production cost.

In an aspect, a photovoltaic cell array is provided. The photovoltaic cell array includes: a plurality of solar cells, each of the plurality of solar cells including: an upper surface, upper segment electrodes located on the upper surface, a lower surface, and lower segment electrodes located on the lower surface; and a flexible metal conductive strip.

The plurality of solar cells includes two adjacent solar cells which are respectively referred to as a first solar cell and a second solar cell.

The first solar cell includes a first overlap region, the second solar cell includes a second overlap region, the flexible metal conductive strip includes a third overlap region, and the second overlap region, the third overlap region and the first overlap region are sequentially stacked in a normal direction of the upper surface of each of the plurality of solar cells.

The lower segment electrodes of the first solar cell are all outside the first overlap region of the first solar cell, and the upper segment electrodes of the second solar cell are all outside the second overlap region of the second solar cell. Only one of the lower segment electrodes of the first solar cell is welded to the flexible metal conductive strip, and only one of the upper segment electrodes of the second solar cell is welded to the flexible metal conductive strip.

In another aspect, a photovoltaic module is provided. The photovoltaic module includes a photovoltaic cell array. The photovoltaic cell array includes: a plurality of solar cells, each of the plurality of solar cells including: an upper surface, upper segment electrodes located on the upper surface, a lower surface, and lower segment electrodes located on the lower surface; and a flexible metal conductive strip.

The plurality of solar cells includes two adjacent solar cells which are respectively referred to as a first solar cell and a second solar cell.

The first solar cell includes a first overlap region, the second solar cell includes a second overlap region, the flexible metal conductive strip includes a third overlap region, and the second overlap region, the third overlap region and the first overlap region are sequentially stacked in a normal direction of the upper surface of each of the plurality of solar cells.

The lower segment electrodes of the first solar cell are all outside the first overlap region of the first solar cell, and the upper segment electrodes of the second solar cell are all outside the second overlap region of the second solar cell. Only one of the lower segment electrodes of the first solar cell is welded to the flexible metal conductive strip, and only one of the upper segment electrodes of the second solar cell is welded to the flexible metal conductive strip.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a cross-sectional view of adjacent two solar cells in a photovoltaic cell array according to the present disclosure in a direction along a short side of each of the adjacent two solar cells;

FIG. 2 is a schematic diagram showing a distribution pattern of metal fine grid wires on a surface of a solar cell;

FIG. 3 is a schematic diagram showing another distribution pattern of metal fine grid wires on a surface of a solar cell;

FIG. 4 is a schematic diagram showing another distribution pattern of metal fine grid wires on a surface of a solar cell;

FIG. 5 is a schematic diagram showing another distribution pattern of metal fine grid wires on a surface of a solar cell;

FIG. 6 is a schematic diagram showing another distribution pattern of metal fine grid wires on a surface of a solar cell;

FIG. 7 is a schematic diagram shows a distribution pattern of metal fine grid wires on a surface of a solar cell in a case that a segment electrode is arranged in parallel to a long side of the solar cell; and

FIG. 8 is a schematic structural diagram of a photovoltaic module according to an embodiment of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

In the following detailed description, although numerous specific details are set forth to provide a thorough understanding of the present disclosure, the present disclosure may also be implemented by other embodiments than embodiments described herein. Those skilled in the art may promote similarly without departing from the connotation of the present disclosure. Therefore, the present disclosure is not limited to the following disclosed specific embodiments.

As described in the background part, in conventional technologies, a front electrode of one solar cell and a back electrode of an adjacent solar cell overlap with each other by adopting conducting resin to form a series circuit. Though output power of a photovoltaic module can be improved to a certain extent, the photovoltaic module has a large package loss, which results in a large power consumption inside the photovoltaic module. In addition, processes such as applying conducting resin, curing and terminal welding and related devices are additionally required, which results in a complex process and a high production cost.

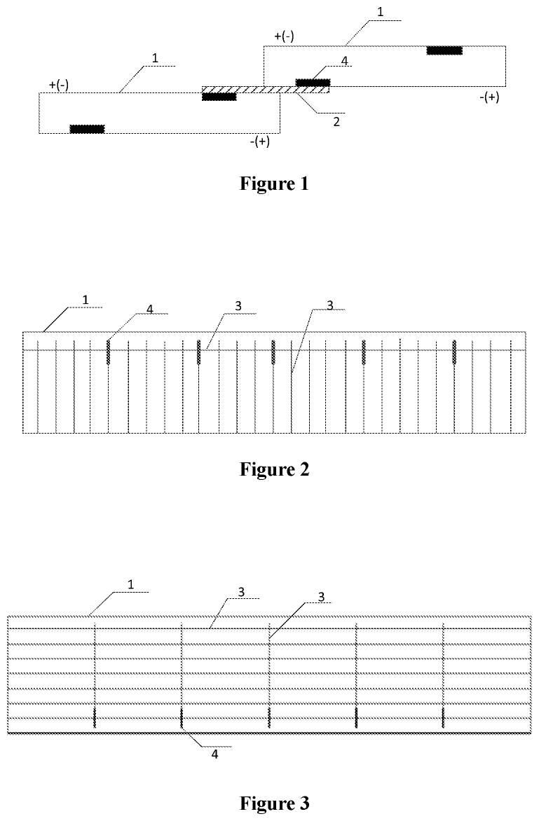

In view of this, a photovoltaic cell array is provided according to the present disclosure. FIG. 1 is a cross-sectional view of adjacent two solar cells in a photovoltaic cell array according to the present disclosure in a direction along a short side of each of the adjacent two solar cells. The photovoltaic cell array includes multiple solar cells 1 and a flexible metal conductive strip 2. Each of an upper surface and a lower surface of each solar cell is arranged with a segment electrode 4. In adjacent two of the multiple solar cells 1 which are respectively referred to as a first solar cell and a second solar cell, the segment electrode 4 on the lower surface of the first solar cell is connected with the segment electrode 4 on the upper surface of the second solar cell with the flexible metal conductive strip 2. In addition, the photovoltaic cell array has a stack structure in a normal direction on the upper surface of the solar cell 1. A connection region at which the segment electrode is connected with the flexible metal conductive strip is located outside an overlapped region of the stack structure.

In the present embodiment, the segment electrode 4 on the lower surface of the first solar cell in the adjacent two solar cells 1 is connected with the segment electrode 4 on the upper surface of the second solar cell in the adjacent two solar cells 1 by the flexible metal conductive strip 2, since the flexible metal conductive strip 2 has a small resistance, the flexible metal conductive strip 2 causes a small power loss when the photovoltaic cell array produces a current after receiving solar radiation, such that the output power of the photovoltaic cell array can be increased. A width of the flexible metal conductive strip 2 is equal to a width of the segment electrode 4.

Specifically, the flexible metal conductive strip may be a solder strip or a flexible conductive strip made of another metallic material.

Further, in the present embodiment, the photovoltaic cell array has the stack structure in the normal direction of the upper surface of the solar cell 1, since the adjacent solar cells 1 are stacked with each other, the number of the solar cells 1 in the photovoltaic cell array can be increased for the photovoltaic cell array with a fixed length, thereby such that a light receiving area is increased, thus improving the output power of the photovoltaic cell array.

Further, in the present embodiment, the connection region at which the flexible metal conductive strip is connected with the segment electrode is located outside the overlapped region of the stack structure, such that it is convenient to perform a rework process when a failure occurs at the connection region such as a loose connection.

It should be noted that, in the present disclosure, the solar cell 1 is a rectangular (quasi rectangular) plate. A ratio of length of a long side to that of a short side of the solar cell 1 ranges from 4 to 20, inclusive.

It should be noted that, in the present embodiment, the solar cell 1 may be obtained by, but not limited to, dividing a square (quasi square) solar cell or another rectangular (quasi rectangular) solar cell.

The segment electrode 4 is configured to collect the current generated by the solar cell and transmits the current to the flexible metal conductive strip 2. For a double-sided solar cell, each of an upper surface and a lower surface of the double-sided solar cell is arranged with metal fine grid wires, and the segment electrode 4 is connected to the metal fine grid wires to collect current. For a single-sided solar cell, an upper surface of the single-sided solar cell is arranged with metal fine grid wires, and a lower surface of the single-sided solar cell is arranged with an aluminum back surface field, rather than the metal fine grid wires. The segment electrode 4 arranged on the upper surface of the single-sided solar cell is connected to the metal fine grid wires, and the segment electrode 4 arranged on the lower surface of the single-sided solar cell is directly connected to the aluminum back surface field.

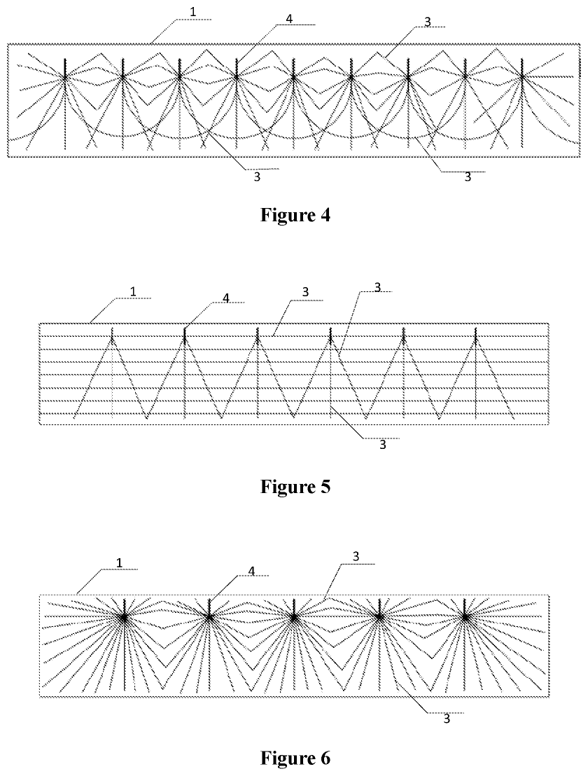

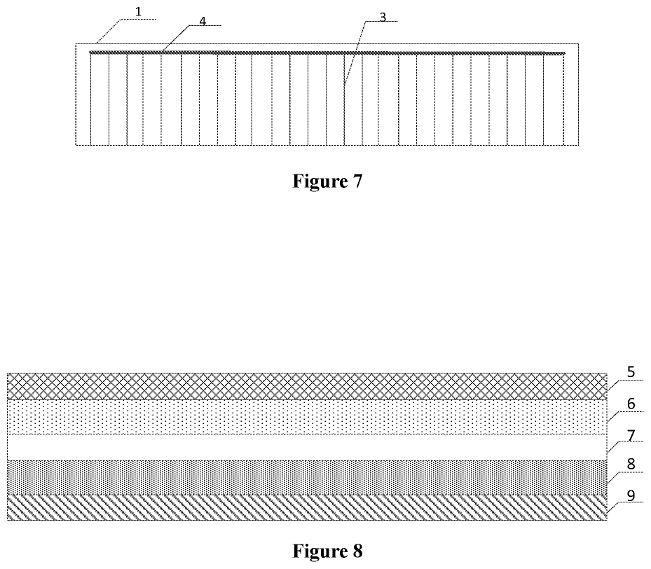

It also should be noted that, in the present embodiment, a distribution patterns of the metal fine grid wires on the upper surface of the double-sided solar cell, the lower surface of the double-sided solar cell and the upper surface of the single-sided solar cell are not limited in the present disclosure, which are determined according to actual needs. FIG. 2 to FIG. 6 show five distribution patterns of metal fine grid wires 3 on a surface of a solar cell. Preferably, for the double-sided solar cell, the metal fine grid wires 3 on the upper surface has the same distribution pattern as the metal fine grid wires 3 on the lower surface, to simplify a production process, so as to improve production efficiency.

It can be understood that, in a case that the lower surface of the first solar cell in the adjacent two solar cells 1 is connected with a negative electrode, the upper surface of the second solar cell is connected with a positive electrode. Similarly, in a case that the lower surface of the first solar cell is connected with a positive electrode, the upper surface of the second solar cell is connected with a negative electrode.

Specifically, in an embodiment of the present disclosure, as shown in FIG. 7, the segment electrode 4 is arranged with a length direction of the segment electrode 4 parallel to the long side of the solar cell 1, but the present disclosure is not limited thereto. In another embodiment of the present disclosure, the segment electrode 4 is arranged with the length direction of the segment electrode 4 perpendicular to the long side of the solar cell 1. In another embodiment of the present disclosure, there is an angle between the segment electrode 4 and a first side of the solar cell 1, which is an acute angle, where the first side is the long side of the solar cell 1. It may be understood that two segment electrodes 4 respectively in adjacent two solar cells 1 are connected to each other by the flexible metal conductive strip 2 such that a positional relationship between the segment electrode 4 and the long side of the solar cell 1 represents a positional relationship between the flexible metal conductive strip 2 and the long side of the solar cell 1. For example, in a case that the segment electrode 4 is arranged with the length direction of the segment electrode 4 perpendicular to the long side of the solar cell 1, the flexible metal conductive strip 2 is arranged perpendicular to the long side of the solar cell 1.

It may also be understood that, regardless of an angle between the segment electrode 4 and a side of the solar cell 1, the segment electrode 4 transmits the collected current to the flexible metal conductive strip 2, and a direction in which the current flows is parallel to the surface of the solar cell 1.

The photovoltaic cell array provided according to the present disclosure includes multiple solar cells 1 and the flexible metal conductive strip 2. Each of an upper surface and a lower surface of each of the multiple solar cells 1 is arranged with a segment electrode 4. In adjacent two of the multiple solar cells 1 which are respectively referred to as a first solar cell and a second solar cell, the segment electrode 4 on the lower surface of the first solar cell is connected with the segment electrode 4 on the upper surface of the second solar cell with the flexible metal conductive strip 2. The photovoltaic cell array has a stack structure in a normal direction of the upper surface of each of the multiple solar cells, and a connection region at which the segment electrode is connected with the flexible metal conductive strip is located outside an overlapped region of the stack structure. In the present disclosure, two adjacent solar cells 1 in the photovoltaic cell array are connected with each other by the flexible metal conductive strip 2, since the flexible metal conductive strip 2 has a low cost, a small resistance, and a small power consumption, the output power of the photovoltaic cell array can be improved and the production cost of the module can be reduced. In addition, since the adjacent two solar cells 1 in the photovoltaic cell array form the stack structure in the normal direction of the upper surface of the solar cell, the number of the solar cells 1 can be increased for the photovoltaic cell array with a fixed length, such that the light receiving area is increased, thereby improving the output power of the photovoltaic cell array. Compared with a conventional module, although output power of an imbricate photovoltaic module is improved, processes such as applying conducting resin, curing and terminal welding and related devices are additionally required, which results in a complex process and a high production cost. However, in the embodiment, the solder strip is adopted, which can simplify the production process and reduce the production cost.

Further, in an embodiment of the present disclosure, in a case that the segment electrode 4 is arranged with the length direction of the segment electrode 4 perpendicular to the long side of the solar cell 1, the number of the segment electrode 4 is not specifically limited according to the present embodiment.

In an embodiment, based on above embodiments, in an embodiment of the present disclosure, the number of the segment electrode 4 may range from 1 to 12, inclusive.

Preferably, in a case that the segment electrode 4 is arranged perpendicular to the first side of the solar cell 1, the number of the segment electrode 4 located on each of the upper surface and the lower surface of the solar cell ranges from 4 to 9, inclusive, where the solar cell 1 is a rectangular plate, and the first side is the long side of the solar cell 1. In addition, it is required to avoid the number of the segment electrodes from being too small, this is because that if the number of the segment electrode is too small, not all current of the solar cells can be collected, resulting in a waste of the current, failing to efficiently improve the output power of the photovoltaic cell array. In addition, it is also required to avoid the number of the segment electrodes 4 from being too large, this is because that the segment electrode 4 is connected to the flexible metal conductive strip 2, such that the solar cell 1 is shielded, which can reduce the light receiving area on the solar cell 1, resulting in a reduced output power of the photovoltaic cell array.

Based on above embodiments, in an embodiment of the present disclosure, in a case that the number of the segment electrodes 4 is two or more, the segment electrodes 4 are arranged uniformly on each of the upper surface and the lower surface of the solar cell.

Based on above embodiments, in an embodiment of the present disclosure, a width of the segment electrode 4 ranges from 0.5 mm to 5 mm, inclusive. It is required to avoid the width of the segment electrode 4 from being too small, this is because that the flexible metal conductive strip 2 is to be welded to the segment electrode 4, a weld region between the flexible metal conductive strip 2 and the segment electrode 4 is weak in a case that the width of the segment electrode 4 is too small. In addition, it is also required to avoid the width of the segment electrode 4 from being too large, because a region in which the segment electrode 4 is located cannot receive light to generate electricity once the flexible metal conductive strip 2 is welded to the segment electrode 4, thus an effective area of the solar cell 1 is reduced, resulting in a reduced overall output power of the photovoltaic cell array.

Based on above embodiments, in an embodiment of the present disclosure, a length of the segment electrode 4 ranges from 1 mm to 15 mm, inclusive. It is required to avoid the length of the segment electrode 4 from being too small, this is because that the flexible metal conductive strip 2 is to be welded to the segment electrode 4, a small contact region may be caused between the flexible metal conductive strip 2 and the segment electrode 4 if the length of the segment electrode 4 is too small, resulting in a weak weld region. In addition, it is required to avoid the length of the segment electrode 4 from being too large, this is because that a region in which the segment electrode 4 is located cannot receive light to produce current, a large region of the solar cell 1 is shielded in a case that the length of the segment electrode 4 is too large, which may reduce the power generation efficiency, resulting in a reduced overall output power of the photovoltaic cell array.

Based on above embodiments, in an embodiment of the present disclosure, a thickness of the flexible metal conductive strip 2 is less than 200 μm. It is required to avoid the thickness of the flexible metal conductive strip 2 from being too large, this is because that adjacent two solar cells 1 are connected in a stack manner by the flexible metal conductive strip 2 and a distance between the adjacent two solar cells 1 is equal to the thickness of the flexible metal conductive strip 2, the distance between the adjacent two solar cells 1 is large in a case that the thickness of the flexible metal conductive strip 2 is large, which may results in a large overall height of the photovoltaic cell array, thereby affecting a use of the photovoltaic cell array. In addition, if the overall height of the photovoltaic cell array is large, in a process of fabricating a photovoltaic module using the photovoltaic cell array, the solar cell 1 of the photovoltaic cell array is easily broken during lamination, which reduces a product qualified rate and increases the production cost.

Preferably, in an embodiment of the present disclosure, the stack structure is formed by stacking the adjacent two solar cells 1 along a first side of each solar cell 1, where the first side is a long side of the solar cell 1. Preferably, the metal fine grid wires 3 are arranged in a direction parallel to a short side of the solar cell 1. The stack structure is formed by stacking adjacent two solar cells 1 along the first side of each solar cell 1, that is, the adjacent two solar cells 1 are stacked along the long side of the solar cell 1. The metal fine grid wires 3 on a surface of the solar cell 1 are used to carry current in the solar cell 1 and transmit the current to the outside of the solar cell 1. A distance through which the current in the metal fine grid wires 3 flows is equal to a length of the short side of the solar cell 1. A short distance through which the current flows cause a small power consumed inside the solar cell 1, thus the output power of the photovoltaic cell array is large. In addition, since the adjacent two solar cells 1 are stacked along the long side of the solar cell 1, the photovoltaic module is fabricated without improving the conventional production equipment, which is realized by a simple process.

Preferably, in an embodiment of the present disclosure, a width of an overlapped region of the stack structure is less than 2 mm. It is required to avoid the width of the overlapped region of the stack structure of the photovoltaic cell array from being too large, this is because that the overlapped region cannot receive light, that is, an effective area of the solar cell 1 is reduced due to the overlapped region, which reduces the overall output power of the photovoltaic cell array.

Preferably, in a case that the solar cells 1 are stacked in the long side of the solar cell 1, a length of the flexible metal conductive strip 2 by which adjacent two solar cells 1 are connected is less than a half of a length of a short side of the solar cell 1.

A photovoltaic module is further provided according to the present disclosure. FIG. 8 is a structural diagram of a photovoltaic module according to an embodiment of the present disclosure. The photovoltaic module includes a glass substrate 5, an EVA photoresist film layer 6, the photovoltaic cell array 7 described in any one of the above embodiments, an EVA photoresist film layer 8 and a backplane 9 that are stacked in the listed sequence from top to bottom.

The photovoltaic cell array in the photovoltaic module according to the present disclosure includes multiple solar cells 1 and the flexible metal conductive strip 2. Each of an upper surface and a lower surface of each of the multiple solar cells 1 is arranged with a segment electrode 4. In adjacent two of the multiple solar cells 1 which are respectively referred to as a first solar cell and a second solar cell, the segment electrode 4 on the lower surface of the first solar cell is connected with the segment electrode 4 on the upper surface of the second solar cell with the flexible metal conductive strip 2. The photovoltaic cell array has a stack structure in a normal direction of the upper surface of each of the multiple solar cells, and a connection region at which the segment electrode is connected with the flexible metal conductive strip is located outside an overlapped region of the stack structure. In the present disclosure, two adjacent solar cells 1 in the photovoltaic cell array are connected with each other by the flexible metal conductive strip 2, since the flexible metal conductive strip 2 has a low cost, a small resistance, and a small power consumption, the output power of the photovoltaic cell array can be improved and the production cost of the module can be reduced. In addition, since the adjacent two solar cells 1 in the photovoltaic cell array form the stack structure in the normal direction of the upper surface of the solar cell, the number of the solar cells 1 can be increased for the photovoltaic cell array with a fixed length, such that the light receiving area is increased, thereby improving the output power of the photovoltaic cell array.

The embodiments in this specification are described in a progressive way, each of which emphasizes the differences from others, and the same or similar parts among the embodiments can be referred to each other. Since the device disclosed in the embodiments is corresponding to the method therein, the description thereof is relatively simple, and for relevant matters references may be made to the description of the method.

The photovoltaic cell array and the photovoltaic module according to the present application are introduced above in detail. Specific examples are used herein to illustrate the principle and embodiments of the present disclosure. The above illustration of the embodiments is only to help in understanding the method and the core idea of the present disclosure. It should be noted that those skilled in the art can change or modify the present disclosure without departing from the principle of the present disclosure and the changes and modifications fall within the protection scope of the claims of the present disclosure.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

The description of the disclosure is merely exemplary in nature and, thus, variations that do not depart from the substance of the disclosure are intended to be within the scope of the disclosure. Such variations are not to be regarded as a departure from the spirit and scope of the disclosure.

What is claimed is:

1. A photovoltaic cell array, comprising:
a plurality of solar cells, each of the plurality of solar cells comprising: an upper surface, upper segment electrodes located on the upper surface, a lower surface, and lower segment electrodes located on the lower surface; and
a flexible metal conductive strip,
wherein the plurality of solar cells comprises a first solar cell and a second solar cell that is adjacent to the first solar cell,
wherein the first solar cell comprises a first overlap region, the second solar cell comprises a second overlap region, the flexible metal conductive strip comprises a third overlap region, and the second overlap region, the third overlap region and the first overlap region are sequentially stacked in a normal direction of the upper surface of each of the plurality of solar cells, and
wherein the lower segment electrodes of the first solar cell are all outside the first overlap region of the first solar cell, and the upper segment electrodes of the second solar cell are all outside the second overlap region of the second solar cell, and wherein only one of the lower segment electrodes of the first solar cell is welded to the flexible metal conductive strip, and only one of the upper segment electrodes of the second solar cell is welded to the flexible metal conductive strip.

2. The photovoltaic cell array according to claim 1, wherein the upper segment electrodes of one solar cell of the plurality of solar cells are perpendicular to a first side of the one solar cell, a number of the upper segment electrodes of the one solar cell ranges from 4 to 9, and wherein the one solar cell is a rectangular plate, and the first side is a long side of the rectangular plate.

3. The photovoltaic cell array according to claim 1, wherein each solar cell further comprises a first edge and a second edge that are opposite each other, the upper segment electrodes of each solar cell are arranged in a direction from the first edge to the second edge, and the lower segment electrodes of each solar cell are arranged in the direction from the first edge to the second edge,
wherein the second edge of the second solar cell is closer to the first edge of the first solar cell than the first edge of the second solar cell, the only one of the lower segment electrodes of the first solar cell is one of the lower segment electrodes that is closest to the first edge of the first solar cell, and the only one of the upper segment electrodes of the second solar cell is one of the upper segment electrodes that is closest to the second edge of the second solar cell.

4. The photovoltaic cell array according to claim 1, wherein the lower segment electrodes of one solar cell of the plurality of solar cells are perpendicular to a first side of the one solar cell, a number of the lower segment electrodes of the one solar cell ranges from 4 to 9, and wherein the one solar cell is a rectangular plate, and the first side is a long side of the rectangular plate.

5. The photovoltaic cell array according to claim 1, wherein a width of each of the upper segment electrodes ranges from 0.5 mm to 5 mm, and a width of each of the lower segment electrodes ranges from 0.5 mm to 5 mm.

6. The photovoltaic cell array according to claim 1, wherein a length of each of the upper segment electrodes ranges from 1 mm to 15 mm, and a length of each of the lower segment electrodes ranges from 1 mm to 15 mm.

7. The photovoltaic cell array according to claim 1, wherein a thickness of the flexible metal conductive strip is less than 200 μm.

8. The photovoltaic cell array according to claim 1, wherein a width of the third overlap region is less than 2 mm.

9. The photovoltaic cell array according to claim 1, wherein the flexible metal conductive strip further comprises a first connection region and a second connection region, the first connection region is welded to the only one of the lower segment electrodes of the first solar cell, and the second connection region is welded to the only one of the upper segment electrodes of the second solar cell, and wherein a total length of the first connection region and the third overlap region is less than a length of the first solar cell, and a total length of the second connection region and the third overlap region is less than a length of the second solar cell.

10. The photovoltaic cell array according to claim 9, wherein the total length of the first connection region and the third overlap region is less than half of the length of the first solar cell, and the total length of the second connection region and the third overlap region is less than half of the length of the second solar cell.

11. A photovoltaic module, comprising a photovoltaic cell array, wherein the photovoltaic cell array comprises a plurality of solar cells and a flexible metal conductive strip,
wherein each of the plurality of solar cells comprises: an upper surface, upper segment electrodes located on the upper surface, a lower surface, and lower segment electrodes located on the lower surface,
wherein the plurality of solar cells comprises two adjacent solar cells which are respectively referred to as a first solar cell and a second solar cell,
wherein the first solar cell comprises a first overlap region, the second solar cell comprises a second overlap region, the flexible metal conductive strip comprises a third overlap region, and the second overlap region, the third overlap region and the first overlap region are sequentially stacked in a normal direction of the upper surface of each of the plurality of solar cells, and
wherein the lower segment electrodes of the first solar cell are all outside the first overlap region of the first solar cell, and the upper segment electrodes of the second solar cell are all outside the second overlap region of the second solar cell, and wherein only one of the lower segment electrodes of the first solar cell is welded to the flexible metal conductive strip, and only one of the upper segment electrodes of the second solar cell is welded to the flexible metal conductive strip.

12. The photovoltaic module according to claim 11, wherein the upper segment electrodes of one solar cell of the plurality of solar cells are perpendicular to a first side of the one solar cell, a number of the upper segment electrodes of the one solar cell ranges from 4 to 9, and wherein the one solar cell is a rectangular plate, and the first side is a long side of the rectangular plate.

13. The photovoltaic module according to claim 11, wherein each solar cell further comprises a first edge and a second edge that are opposite to each other, the upper segment electrodes of each solar cell are arranged in a direction from the first edge to the second edge, and the lower segment electrodes of each solar cell are arranged in the direction from the first edge to the second edge,
wherein the second edge of the second solar cell is closer to the first edge of the first solar cell than the first edge of the second solar cell, the only one of the lower segment electrodes of the first solar cell is one of the lower segment electrodes that is closest to the first edge of the first solar cell, and the only one of the upper segment electrodes of the second solar cell is one of the upper segment electrodes that is closest to the second edge of the second solar cell.

14. The photovoltaic module according to claim 11, wherein the lower segment electrodes of one solar cell of the plurality of solar cells are perpendicular to a first side of the one solar cell, a number of the lower segment electrodes of the one solar cell ranges from 4 to 9, and wherein the one solar cell is a rectangular plate, and the first side is a long side of the rectangular plate.

15. The photovoltaic module according to claim 11, wherein a width of each of the upper segment electrodes ranges from 0.5 mm to 5 mm, and a width of each of the lower segment electrodes ranges from 0.5 mm to 5 mm.

16. The photovoltaic module according to claim 11, wherein a length of each of the upper segment electrodes ranges from 1 mm to 15 mm, and a length of each of the lower segment electrodes ranges from 1 mm to 15 mm.

17. The photovoltaic module according to claim 11, wherein a thickness of the flexible metal conductive strip is less than 200 μm.

18. The photovoltaic module according to claim 11, wherein a width of the third overlap region is less than 2 mm.

19. The photovoltaic module according to claim 11, wherein the flexible metal conductive strip further comprises a first connection region and a second connection region, the first connection region is welded to the only one of the lower segment electrodes of the first solar cell, and the second connection region is welded to the only one of the upper segment electrodes of the second solar cell, and wherein a total length of the first connection region and the third overlap region is less than a length of the first solar cell, and a total length of the second connection region and the third overlap region is less than a length of the second solar cell.

20. The photovoltaic module according to claim 19, wherein the total length of the first connection region and the third overlap region is less than half of the length of the first solar cell, and the total length of the second connection region and the third overlap region is less than half of the length of the second solar cell.
